(19) United States
(12) Patent Application Publication
(10) Pub. No.: US 2009/0266585 A1
(43) Pub. Date: Oct. 29, 2009

(54) Flame-Retardant Composition for Solder Resist and Cured Product Thereof

(75) Inventor: Yoshio Miyajima, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SHOWDA DENKO K.K., TOKYO (JP)

(21) Appl. No.: 11/887,394

(22) PCT Filed: Mar. 24, 2006
(86) PCT No.: PCT/JP2006/306767

§ 371 Date: Sep. 28, 2007

Related U.S. Application Data
(60) Provisional application No. 60/669,892, filed on Apr. 11, 2005.

(30) Foreign Application Priority Data
Mar. 31, 2005 (JP) 2005-104586

(51) Int. Cl. H05K 1/02; C08J 3/28; G03F 7/20; B05D 3/02; G03F 7/004; B32B 27/38; B32B 27/08

(52) U.S. Cl. 174/254; 522/109; 522/64; 522/81; 522/83; 430/325; 427/386; 430/280.1; 428/413; 430/319; 174/258

(57) ABSTRACT

There is provided a flame retardant composition for a solder resist which is halogen-free and has a high level of flame retardance and flexibility, while exhibiting excellent heat resistance, moisture resistance and high-temperature reliability. The flame retardant composition for a solder resist according to the invention comprises (A) an alkali-soluble resin comprising either or both (A1) a carboxyl group-containing epoxy (meth)acrylate or (A2) a carboxyl group-containing urethane (meth)acrylate obtained by reacting an epoxy resin with two or more epoxy groups in the molecule (a), an unsaturated group-containing monocarboxylic acid (b) and a polybasic acid anhydride (c), (B) a compound having an ethylenic unsaturated group in the molecule, (C) a photopolymerization initiator, (D) a phosphorus-containing epoxy resin having a specific structure and (E) a hydrated metal compound. The composition of the invention can be suitably used as a solder resist or cover lay film for an FPC.

### CROSS-REFERENCES TO RELATED APPLICATIONS

This application claims benefits under 35 U.S.C. §119(e) to U.S. Provisional Application Ser. No. 60/669,892 filed Apr. 11, 2005.

### TECHNICAL FIELD

The present invention relates to a halogen-free flame retardant curing composition which reacts with sensitivity to active energy rays and can be developed with a dilute aqueous alkali solution, and which when used as a solder resist, photosensitive cover lay, interlayer insulating film or the like on a printed circuit board, forms a coated film with excellent flexibility, adhesion, electroless gold plating resistance and insulating properties, as well as excellent flame retardance.

### BACKGROUND ART

Production of printed circuit boards has conventionally required various board protecting means such as resists during etching and solder resists used in soldering steps. In the production processes for film-like printed circuit boards as well (flexible printed circuit boards, FPC), which are used in miniature devices and the like, solder resists are required for protection of unrelated circuits in the soldering steps carried out for mounting of parts.

Such board protecting means have conventionally included cover layer films obtained by lamination of a polyimide film punched into a specified form, and cover coats obtained by printing an ink composed of a heat resistant material. Cover lay films and cover coats also serve as protecting films for soldered circuits, and must therefore exhibit heat resistance and insulating properties during soldering, as well as flexibility so that cracks are not generated upon bending during integration of the board. Flame retardance is also often required.

Cover lay films formed by punching of a polyimide film satisfy the required properties described above and are therefore the most widely used at the current time, but they are associated with such problems as costly dies for punch molding, and even higher cost for manual positioning and attachment of the punched films, as well as difficulty in forming intricate patterns. Cover coats have high production cost since a drying step is necessary for the screen printing, and workability is also poor.

As a method for solving these problem there has been proposed a method of coating the base with a photosensitive composition in liquid form, or attaching it thereto in film form. This method allows cover coats and cover lay films with intricate patterns to be easily formed on boards by forming coatings and then exposing, developing and heating them by photographic techniques, and various different types of photosensitive compositions have been developed as a result.

However, no conventional photosensitive compositions have existed which satisfy all of the properties required for FPC use. For example, one composition that has been proposed is a photosensitive composition comprising a prepolymer obtained by addition reaction of a polybasic acid anhydride with a novolac-type epoxy vinyl ester resin, and a photopolymerization initiator, a diluent and an epoxy resin (Japanese Examined Patent Publication HEI No. 1-54390 (see Patent document 1)), but although this composition has satisfactory heat resistance and insulating properties, it is inflexible and unsuitable for FPCs. There has also been proposed a photosensitive composition obtained by mixing an acrylated urethane monomer component, a photopolymerization initiator and a block diisocyanate crosslinking agent to a binder system comprising a low molecular weight copolymer, which is the reaction product of a copolymer formed from an ethylenic unsaturated dicarboxylic acid anhydride and an ethylenic unsaturated comonomer, with an amine, and a carboxylic acid-containing high molecular weight copolymer (Japanese Unexamined Patent Publication HEI No. 7-278492 (see Patent document 2)), but this composition is not flame retardant and is limited in its uses.

Conventional methods for imparting flame retardance to photosensitive compositions include methods of using flame retardant agent systems obtained by combining a halogenated flame retardant agent such as a brominated epoxy resin, with a flame retardant aid such as antimony trioxide (Japanese Unexamined Patent Publication HEI No. 9-325490 (see Patent document 3), Japanese Unexamined Patent Publication HEI No. 11-242331 (see Patent document 4)). However, these flame retardant agent systems often have inferior reliability in high-temperature environments, and when employing antimony compounds it becomes necessary to consider the environmental issue of resin waste treatment. In addition, brominated epoxy resins have the disadvantage of impairing flexibility when added in amounts sufficient to produce a flame retardant effect.

On the other hand, methods using phosphoric acid esters as flame retardant agents have also been proposed (Japanese Unexamined Patent Publication HEI No. 9-235449 (see Patent document 5), Japanese Unexamined Patent Publication HEI No. 10-306201 (see Patent document 6), Japanese Unexamined Patent Publication HEI No. 11-271967 (see Patent document 7)), but the flame retardant effects are weak with phosphoric acid esters alone and therefore the use of a large amount of phosphoric acid ester to achieve the flame retardant effect has been unavoidable, while bleed-out of the phosphoric acid ester on the surface of the cured film has been a problem. A flame retardant photosetting/thermosetting resin composition comprising a specific cycloalkylenephosphine derivative has also been proposed (Japanese Unexamined Patent Publication No. 2003-192763 (see Patent document 8)), but the specific cycloalkylenephosphine derivative is poorly soluble or insoluble in ordinary organic solvents. Consequently, sufficient pulverization steps are necessary for use in fine printed circuit boards having a circuit conductor line-and-space of 25 μm or smaller.

There have additionally been proposed flame retardant photosetting/thermosetting resin compositions characterized by comprising a specific organic phosphorus compound and a carboxyl group-containing photosensitive resin obtained by reacting a polybasic acid anhydride with a reaction product obtained by reacting an unsaturated group-containing monocarboxylic acid with the reaction product of a novolac-type phenol resin and an alkylene oxide (Japanese Unexamined Patent Publication No. 2003-277470 (see Patent document 9)), but these are associated with problems of poor PCT resistance and electroless gold plating resistance.

Thus, it has not been easy to obtain resist films with the high flame retardance, flexibility and tack-free properties satisfying UL standards, with excellent soldering heat resistance, moisture resistance and high-temperature reliability as well, and therefore further improvements have been desired.

[Patent document 1] Japanese Examined Patent Publication HEI No. 1-54390

[Patent document 2] Japanese Unexamined Patent Publication HEI No. 7-278492

[Patent document 3] Japanese Unexamined Patent Publication HEI No. 9-325490

[Patent document 4] Japanese Unexamined Patent Publication HEI No. 11-242331

[Patent document 5] Japanese Unexamined Patent Publication HEI No. 9-235449

[Patent document 6] Japanese Unexamined Patent Publication HEI No. 10-306201

[Patent document 7] Japanese Unexamined Patent Publication HEI No. 11-271967

[Patent document 8] Japanese Unexamined Patent Publication No. 2003-192763

[Patent document 9] Japanese Unexamined Patent Publication No. 2003-277470

### SUMMARY OF THE INVENTION

It is an object of the present invention to provide a flame retardant composition for a solder resist which is halogen-free, has a high level of flame retardance, flexibility and tack-free property, while exhibiting excellent soldering heat resistance, moisture resistance and high-temperature reliability, and particularly a flame retardant composition that can be suitably used as a cover lay film, solder resist or the like for FPCs. It is another object of the invention to provide a method that can satisfactorily form a heat resistant protective film using the flame retardant composition.

As a result of much diligent research, the present inventors have completed this invention based on the discovery that the aforementioned problems can be solved by using a flame retardant agent with a specific composition. Specifically, the invention relates to a flame retardant composition for a solder resist and its cured product, as laid out in [1] to [34] below.

[1] A flame retardant composition for a solder resist, characterized by comprising

(A) an alkali-soluble resin comprising either or both (A1) a carboxyl group-containing epoxy (meth)acrylate or (A2) a carboxyl group-containing urethane (meth)acrylate obtained by reacting an epoxy resin with two or more epoxy groups in the molecule (a), an unsaturated group-containing monocarboxylic acid (b) and a polybasic acid anhydride (c);

(B) a compound having an ethylenic unsaturated group in the molecule;

(C) a photopolymerization initiator;

(D) a phosphorus-containing epoxy resin obtained by reacting an epoxy resin with two or more epoxy groups in the molecule (d) with a phosphorus-containing compound represented by the following general formula (1) or (2):

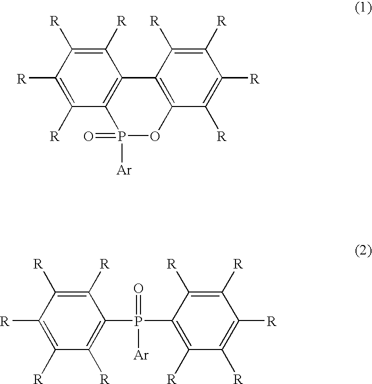

{wherein each R independently represents hydrogen or a C1-6 organic group containing no halogen, and Ar represents the reaction residue of a quinone compound represented by the following general formula (3) or (4):

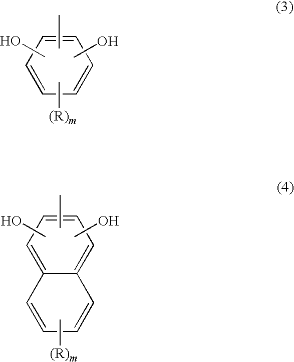

(wherein each R independently represents hydrogen or a C1-6 organic group containing no halogen, and m represents an integer of 0-3)}
or represented by the following general formula (5) or (6):

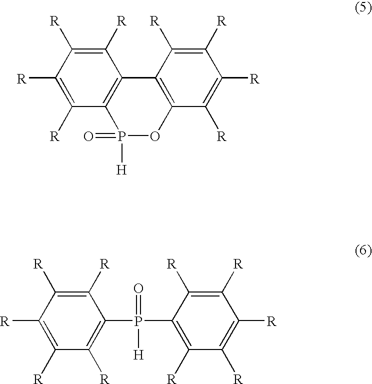

{wherein each R independently represents hydrogen or a C1-6 organic group containing no halogen}; and

(E) a hydrated metal compound.

[2] A flame retardant composition for a solder resist according to [1] above, characterized in that the carboxyl group-containing epoxy (meth)acrylate (A1) is a carboxyl group-containing bisphenol-type epoxy (meth)acrylate (A1-1).

[3] A flame retardant composition for a solder resist according to [1] or [2] above, characterized in that the alkali-soluble resin (A) has a solid portion acid value of 30-150 mgKOH/g, a weight-average molecular weight of 4000-40,000 and a glass transition temperature of −60° C. to 60° C.

[4] A flame retardant composition for a solder resist according to any one of [1] to [3] above, wherein the polybasic acid anhydride (c) is a polybasic acid anhydride selected from the group consisting of phthalic anhydride, tetrahydrophthalic anhydride, hexahydrophthalic anhydride, methylhexahydrophthalic anhydride, endomethylenetetrahydrophthalic anhydride and methylendomethylenetetrahydrophthalic anhydride.

[5] A flame retardant composition for a solder resist according to any one of [1] to [4] above, wherein 30-100 wt % of the alkali-soluble resin (A) is a carboxyl group-containing urethane (meth)acrylate (A2).

[6] A flame retardant composition for a solder resist according to any one of [1] to [5] above, wherein the compound having an ethylenic unsaturated group in the molecule (B) is urethane acrylate (B-1).

[7] A flame retardant composition for a solder resist according to any one of [1] to [6] above, wherein 70-100 wt % of the compound having an ethylenic unsaturated group in the molecule (B) is a compound having two ethylenic unsaturated groups in the molecule.

[8] A flame retardant composition for a solder resist according to any one of [1] to [7] above, wherein 20-95 wt % of the photopolymerization initiator (C) is a phosphorus-containing photopolymerization initiator.

[9] A flame retardant composition for a solder resist according to any one of [1] to [8] above, wherein the epoxy equivalent of the phosphorus-containing epoxy resin (D) is 200-700 g/eq.

[10] A flame retardant composition for a solder resist according to any one of [1] to [9] above, wherein the phosphorus content of the phosphorus-containing epoxy resin (D) is in the range of 1-9 wt %.

[11] A flame retardant composition for a solder resist according to any one of [1] to [10] above, wherein the content of the phosphorus-containing epoxy resin (D) in the solid portion of the flame retardant composition for a solder resist is in the range of 5-40 wt %.

[12] A flame retardant composition for a solder resist according to any one of [1] to [11] above, wherein the endotherm during thermal decomposition of the hydrated metal compound (E) is 400-2500 J/g.

[13] A flame retardant composition for a solder resist according to any one of [1] to [12] above, wherein the hydrated metal compound (E) is aluminum hydroxide and/or magnesium hydroxide.

[14] A flame retardant composition for a solder resist according to any one of [1] to [13] above, wherein the content of the hydrated metal compound (E) in the solid portion of the flame retardant composition for a solder resist is in the range of 5-40 wt %.

[15] A flame retardant composition for a solder resist according to any one of [1] to [14] above, wherein the hydrated metal compound (E) is a hydrated metal compound treated with a coupling agent at a proportion of 0.3-3.0 wt %.

[16] A flame retardant composition for a solder resist according to any one of [1] to [15] above, which further comprises (F) an organic solvent.

[17] A flame retardant composition for a solder resist according to any one of [1] to [16] above, which further comprises (G) an epoxy resin other than the phosphorus-containing epoxy resin (D).

[18] A flame retardant composition for a solder resist according to any one of [1] to [17] above, which further comprises (H) a phosphoric acid ester compound with a melting point of 75° C. to 150° C.

[19] A flame retardant composition for a solder resist according to any one of [1] to [18] above, which further comprises (I) an epoxy thermosetting accelerator.

[20] A flame retardant composition for a solder resist according to any one of [1] to [19] above, wherein the epoxy thermosetting accelerator (I) has a triazine skeleton.

[21] A flame retardant composition for a solder resist according to any one of [1] to [20] above, which further comprises (J) a halogen-free coloring agent.

[22] A flame retardant composition for a solder resist according to [21] above, wherein the mixing proportions in the flame retardant composition for a solder resist are 30-70 wt % of the alkali-soluble resin (A), 3-20 wt % of the compound having an ethylenic unsaturated group in the molecule (B), 1-10 wt % of the photopolymerization initiator (C), 5-25 wt % of the phosphorus-containing epoxy resin (D), 5-30 wt % of the hydrated metal compound (E), 10-60 wt % of the organic solvent (F), 0-10 wt % of the epoxy resin (G) other than the phosphorus-containing epoxy resin (D), 2-10 wt % of the phosphoric acid ester compound (H), 0.1-3 wt % of the epoxy thermosetting accelerator (I) and 0.05-2 wt % of the coloring agent (J).

[23] A flame retardant composition for a solder resist according to any one of [1] to [22] above, wherein the phosphorus content of the solid portion of the flame retardant composition for a solder resist is 1.0-5.0 wt %.

[24] A flame retardant composition for a solder resist according to any one of [1] to [23] above, characterized by having a viscosity of 500-500,000 mPa·s (25° C.)

[25] A cured composition characterized by being obtained by curing a flame retardant composition for a solder resist according to any one of [1] to [24] above.

[26] A method for curing a flame retardant composition, characterized by coating a base with a flame retardant composition for a solder resist according to any one of [1] to [24] above and drying for 1-30 minutes in a temperature range of 50-120° C. to a thickness of 5-100 μm, and then subjecting it to exposure, development and thermosetting.

[27] A flame retardant cover lay film characterized by comprising a photosensitive layer formed from a flame retardant composition for a solder resist according to any one of [1] to [24] above, on a support.

[28] A flame retardant cover lay film according to [27] above, characterized in that the support is a polyester film.

[29] A method for production of a flame retardant cover lay film, characterized by coating a flame retardant composition for a solder resist according to any one of [1] to [24] above onto a support and drying it, to form a photosensitive layer.

[30] An insulating protective film comprising a flame retardant composition for a solder resist according to any one of [1] to [24] above.

[31] A printed circuit board characterized by comprising an insulating protective film according to [30] above.

[32] A flexible printed circuit board characterized by comprising an insulating protective film according to [30] above.

[33] A method for production of a printed circuit board, characterized by comprising an attachment step in which the photosensitive layer of a flame retardant cover lay film according to [27] or [28] above is attached to a base, an exposure step in which the photosensitive layer is exposed, a development step following the exposure step and a thermosetting step in which the photosensitive layer is thermoset.

[34] An electronic part characterized by comprising a cured composition according to [25] above.

### DETAILED DESCRIPTION OF THE INVENTION

The method of obtaining the carboxyl group-containing epoxy (meth)acrylate (A1) to be used for the invention may be reaction between an epoxy resin (a), an unsaturated group-containing monocarboxylic acid (b) and a polybasic acid anhydride (c). The epoxy resin (a) used here is preferably an epoxy resin containing no halogen atoms, because the present invention exhibits an excellent flame retardant effect even without a halogen. An epoxy resin containing no halogen atoms is an epoxy resin containing no halogen atoms in the starting phenol resin that is reacted with epichlorhydrin during production of the epoxy resin, or an epoxy resin that is substantially unmodified with halogen atoms. In other words, it may contain the chlorine included by the normal use of epichlorhydrin, and specifically it preferably has a halogen atom content of no greater than about 5000 ppm. More specifically, there may be mentioned bisphenol-type epoxy resins such as bisphenol A-type epoxy resins, bisphenol F-type epoxy resins, bisphenol AD-type epoxy resins, tetramethylbisphenol A-type epoxy resins and bisphenol S-type epoxy resins, bifunctional-type epoxy resins such as resorcinol diglycidyl ether, 1,6-dihydroxynaphthalene diglycidyl ether and dimethylbisphenol C diglycidyl ether, naphthalene-based epoxy resins such as 1,6-diglycidyloxynaphthalene-type epoxy resins, 1-(2,7-diglycidyloxynaphthyl)-1-(2-glycidyloxynaphthyl)methane, 1,1-bis(2,7-diglycidyloxynaphthyl)methane and 1,1-bis(2,7-diglycidyloxynaphthyl)-1-phenyl-methane, novolac-type epoxy resins such as phenolnovolac-type epoxy resins, orthocresol novolac-type epoxy resins, bisphenol A novolac-type epoxy resins and bisphenol AD novolac resins, cyclic aliphatic epoxy resins such as cyclohexene oxide group-containing epoxy resins, tricyclodecene oxide group-containing epoxy resins, cyclopentene oxide group-containing epoxy resins and epoxified dicyclopentadiene-type phenol resins, glycidyl ester-type epoxy resins such as phthalic acid diglycidyl ester, tetrahydrophthalic acid diglycidyl ester, hexahydrophthalic acid diglycidyl ester, diglycidyl p-oxybenzoic acid, dimer acid glycidyl ester and triglycidyl ester, glycidyl amine-type epoxy resins such as diglycidyl aniline, tetraglycidylamino diphenylmethane, triglycidyl-p-aminophenol, etraglycidylmetaxylylene diamine, diglycidyl toluidine and tetraglycidylbisaminomethylcyclohexane, hydantoin-type epoxy resins such as diglycidyl hydantoin and glycidylglycidoxy alkyl hydantoin, heterocyclic epoxy resins such as triallyl isocyanurate and triglycidyl isocyanurate, trifunctional-type epoxy resins such as fluoroglycinol triglycidyl ether, trihydroxybiphenyl triglycidyl ether, trihydroxyphenylmethane triglycidyl ether, glycerin triglycidyl ether, 2-[4-(2,3-epoxypropoxy)phenyl]-2-[4-[1,1-bis[4-(2,3-epoxypropoxy)phenyl]ethyl]phenyl]propane and 1,3-bis[4-[1-[4-(2,3-epoxypropoxy)phenyl]-1-[4-[1-[4-(2,3-epoxypropoxy)phenyl]-1-methylethyl]phenyl]ethyl]phenoxy]-2-propanol, and tetrafunctional-type epoxy resins such as tetrahydroxyphenylethane tetraglycidyl ether, tetraglycidylbenzophenone, bisresorcinol tetraglycidyl ether and tetraglycidoxybiphenyl.

The epoxy resin (a) may be limited to a single type, or may be a combination of two or more types. Also, a portion of each of the aforementioned epoxy resins may be used together with a monofunctional epoxy compound such as n-butylglycidyl ether, allylglycidyl ether, 2-ethylhexylglycidyl ether, styrene oxide, phenylglycidyl ether, cresylglycidyl ether, glycidyl methacrylate or vinylcyclohexene monoepoxide. Particularly preferred among these are bisphenol A-type epoxy resins and/or bisphenol F-type epoxy resins.

As representative examples for the aforementioned unsaturated group-containing monocarboxylic acid (b) there may be mentioned acrylic acid and methacrylic acid, as well as unsaturated dibasic acid anhydride addition products of hydroxyl group-containing (meth)acrylates such as hydroxyethyl (meth)acrylate, hydroxypropyl (meth)acrylate, hydroxybutyl (meth)acrylate, trimethylolpropane di(meth)acrylate, pentaerythritol tri(meth)acrylate, dipentaerythritol penta(meth)acrylate, phenylglycidyl (meth)acrylate and (meth)acrylic acid caprolactone addition product. Particularly preferred among these are acrylic acid and/or methacrylic acid. A single type of unsaturated group-containing monocarboxylic acid may be used, or two or more types may be used in combination.

As representative examples for the aforementioned polybasic acid anhydride (c) there may be mentioned dibasic acid anhydrides such as maleic anhydride, succinic anhydride, itaconic anhydride, phthalic anhydride, tetrahydrophthalic anhydride, hexahydrophthalic anhydride, methylhexahydrophthalic anhydride, endomethylenetetrahydrophthalic anhydride, methylendomethylenetetrahydrophthalic anhydride, chlorendic anhydride and methyltetrahydrophthalic anhydride, aromatic polyvalent carboxylic acid anhydrides such as trimellitic anhydride, pyromellitic anhydride and benzophenonetetracarboxylic dianhydride, and 5-(2,5-dioxotetrahydrofuryl)-3-methyl-3-cyclohexen-en-1,2-dicarboxylic anhydride and endobicyclo-[2,2,1]-hepto-5-en-2,3-dicarboxylic anhydride. Preferred among these, from the standpoint of PCT resistance and HHBT resistance when the solder resist flame retardant composition is cured, are polybasic acid anhydrides selected from the group consisting of phthalic anhydride, tetrahydrophthalic anhydride, hexahydrophthalic anhydride, methylhexahydrophthalic anhydride, endomethylenetetrahydrophthalic anhydride and methylendomethylenetetrahydrophthalic anhydride. Particularly preferred are tetrahydrophthalic anhydride and hexahydrophthalic anhydride. These may be used alone or in combinations of two or more.

The reaction between the epoxy resin (a), the unsaturated group-containing monocarboxylic acid (b) and the polybasic acid anhydride (c) may be either by a first method of reacting the unsaturated group-containing monocarboxylic acid (b) with the epoxy resin (a) and then reacting the polybasic acid anhydride (c) therewith, or by a second method of simultaneously reacting the epoxy resin (a), the unsaturated group-containing monocarboxylic acid (b) and the polybasic acid anhydride (c). The reaction is carried out with the unsaturated group-containing monocarboxylic acid (b) in a proportion of preferably about 0.7-1.4 moles, and more preferably about 0.9-1.1 moles, to one equivalent of epoxy groups of the epoxy resin (a). The reaction between this reaction product (I) and the polybasic acid anhydride (c) is preferably carried out with the polybasic acid anhydride (c) at about 0.1-1 equivalent to one equivalent of hydroxyl groups in the reaction product (I). These reactions are both conducted either in the presence of or in the absence of a reaction solvent, and preferably in the presence of a polymerization inhibitor such as hydroquinone, methylhydroquinone or oxygen, at a reaction temperature of about 50-150° C. and a reaction time of approximately 1-10 hours. Examples of preferred reaction solvents include aromatic hydrocarbons such as benzene, toluene and xylene; ketones such as methyl isobutyl ketone and methyl ethyl ketone; hydrocarbons such as n-hexane, cyclohexane and methylcyclohexane; ethers such as diisopropyl ether; and acetic acid esters such as ethyleneglycol monoethylether acetate, ethyleneglycol monobutylether acetate, diethyleneglycol monoethylether acetate, diethyleneglycol monobutylether acetate, propyleneglycol monomethylether acetate and dipropyleneglycol monomethylether acetate. These solvents may be used alone or in mixtures of two or more.

As an example of the carboxyl group-containing urethane (meth)acrylate (A2) there may be mentioned a compound comprising a unit derived from a hydroxyl group-containing (meth)acrylate compound (d), a unit derived from a diol (e) and a unit derived from a diisocyanate (f), as the structural units. In this type of compound, both ends consist of a unit derived from a hydroxyl group-containing (meth)acrylate (d), and between both ends are situated a unit derived from a diol (e) and a unit derived from a diisocyanate (f), which are urethane bond-linked. Several of the urethane bond-linked repeating units have a structure containing a carboxyl group.

Specifically, the carboxyl group-containing urethane (meth)acrylate (A2) is represented by —(ORbO—CONHRcNHCO)ₙ— [where ORbO represents the dehydrogenation residue of the diol (e) and Rc represents the de-isocyanated residue of the diisocyanate (f)]. The carboxyl group-containing urethane (meth)acrylate (A2) may be produced by reacting at least a hydroxyl group-containing (meth)acrylate (d), a diol (e) and a diisocyanate (f), and either or both the diol (e) and/or diisocyanate (f) must be a compound with a carboxyl group. Preferably, a carboxyl group-containing diol is used.

By using a carboxyl group-containing compound for the diol (e) and/or diisocyanate (f), it is possible to produce a urethane (meth)acrylate compound (A2) with a carboxyl group present in Rb or Rc.

When two or more different compounds are used for either or both the diol (e) and/or diisocyanate (f), a plurality of repeating units will be present, and the regularity of units may be selected from among complete randomness, block or localized, depending on the purpose.

For the hydroxyl group-containing (meth)acrylate (d) there may be mentioned 2-hydroxyethyl (meth)acrylate, hydroxypropyl (meth)acrylate, hydroxybutyl (meth)acrylate, caprolactone or alkylene oxide addition products of the aforementioned (meth)acrylates, glycerin mono(meth)acrylate, glycerin di(meth)acrylate, glycidyl methacrylate-acrylic acid addition product, trimethylolpropane (meth)acrylate, trimethylol di(meth)acrylate, pentaerythritol tri(meth)acrylate, dipentaerythritol penta(meth)acrylate, ditrimethylolpropane tri(meth)acrylate, trimethylolpropane-alkylene oxide addition product—di(meth)acrylate and the like. These hydroxyl group-containing (meth)acrylates (d) may be used alone or in combinations of two or more. Preferred among them are 2-hydroxyethyl (meth)acrylate, hydroxypropyl (meth)acrylate and hydroxybutyl (meth)acrylate, with 2-hydroxyethyl (meth)acrylate being most preferred.

The diol (e) is a compound which, together with the diisocyanate (f), forms a repeating unit of a carboxyl group-containing urethane (meth)acrylate compound (A2). The diol (e) used may be a branched or straight-chain compound with two alcoholic hydroxyl groups. Specifically, there may be mentioned low molecular weight diols such as ethylene glycol, diethylene glycol, propylene glycol, 1,4-butanediol, 1,3-butanediol, 1,5-pentanediol, neopentyl glycol, 3-methyl-1,5-pentanediol, 1,6-hexanediol, 1,4-cyclohexanedimethanol and hydroquinone. There may further be mentioned high molecular weight diols, including polyether-based diols such as polyethylene glycol, polypropylene glycol and polytetramethylene ether glycol, polyester-based diols obtained from ester of polyhydric alcohols and polybasic acids, polycarbonate-based diols such as hexamethylene carbonate and pentamethylene carbonate, and polylactone-based diols such as polycaprolactone diols and polybutyrolactone diols. Using a diol with a number-average molecular weight of about 300-2000 is preferred for more excellent flexibility of the cured film obtained from the photosensitive composition.

As carboxyl group-containing diols there may be mentioned dimethylolpropionic acid and dimethylolbutanoic acid. The diol used may be a single type or a combination of two or more different types, and preferably there is used a combination of a diol with a number-average molecular weight of about 300-2000 and dimethylolpropionic acid and/or dimethylolbutanoic acid.

As diisocyanates (f) to be used for the invention there may be mentioned, specifically, diisocyanates such as 2,4-tolylene diisocyanate, 2,6-tolylene diisocyanate, isophorone diisocyanate, hexamethylene diisocyanate, diphenylmethylene diisocyanate, (o, m or p)-xylylene diisocyanate, methylenebis (cyclohexylisocyanate), trimethylhexamethylene diisocyanate, cyclohexane-1,3-dimethylene diisocyanate, cyclohexane-1,4-dimethylene diisocyanate and 1,5-naphthalene diisocyanate. These diisocyanates may be used alone or in combinations of two or more.

The carboxyl group-containing urethane (meth)acrylate compound (A2) may be produced by (1) a method in which the hydroxyl group-containing (meth)acrylate (d), diol (e) and diisocyanate (f) are mixed all at once for reaction, (2) a method in which the diol (e) and diisocyanate (f) are reacted to produce a urethane isocyanate prepolymer containing at least one isocyanate group per molecule, and then the urethane isocyanate prepolymer is reacted with the hydroxyl group-containing (meth)acrylate (d), or (3) a method in which the hydroxyl group-containing (meth)acrylate (d) is reacted with the diisocyanate (f) to produce a urethane isocyanate prepolymer containing at least one isocyanate group per molecule, and then this prepolymer is reacted with the diol (e).

The content of the carboxyl group-containing urethane (meth)acrylate compound (A2) in the alkali-soluble resin (A) is preferably about 30-100 wt %.

The solid portion acid value of the alkali-soluble resin (A) is preferably in the range of about 30-150 mgKOH/g and more preferably in the range of about 40-120 mgKOH/g. If the solid portion acid value is less than about 30 mgKOH/g the alkali solubility may be poor, and if the solid portion acid value is greater than about 150 mgKOH/g, the cured film may have reduced resist properties such as alkali resistance or electrical characteristics, depending on the combination of constituent components of the flame retardant composition for a solder resist. The solid portion acid value is the net acid value of the alkali-soluble resin (A).

The weight-average molecular weight of the alkali-soluble resin (A) is preferably about 4000-40,000. The weight-average molecular weight is the value measured by gel permeation chromatography, in terms of polystyrene. If the weight-average molecular weight is less than approximately 4000, the ductility and strength of the cured film of the photosensitive composition may be impaired, and if it exceeds approximately 40,000, the alkali solubility may be poor.

The glass transition temperature of the alkali-soluble resin (A) is preferably −60° C. to 60° C. and more preferably −40° C. to 60° C. The glass transition temperature is determined by increasing the temperature from about −120° C. to 180° C. at a temperature-elevating rate of about 10° C./min by DSC in a nitrogen atmosphere, holding at about 180° C. for approximately 3 minutes, cooling to about −120° C. at a temperature-lowering rate of about 10° C./min, and recording the reverse curve point. If the glass transition temperature is higher than 60° C., it will not be possible to achieve satisfactory flexibility for the cured flame retardant composition for a solder resist, and if the glass transition temperature if below −60° C., the soldering heat resistance of the cured flame retardant composition for a solder resist will be lower.

(Meth)acrylates and the like may be used as the compound (B) having an ethylenic unsaturated bond in the molecule. As (meth)acrylates there may be mentioned alkyl (meth)acrylates such as methyl (meth)acrylate, ethyl (meth)acrylate, propyl (meth)acrylate, butyl (meth)acrylate, isobutyl (meth)acrylate, sec-butyl (meth)acrylate, tert-butyl (meth)acrylate, hexyl (meth)acrylate, octyl (meth)acrylate, isooctyl (meth)acrylate, 2-ethylhexyl (meth)acrylate, decyl (meth)acrylate, lauryl (meth)acrylate and stearyl (meth)acrylate;

alicyclic (meth)acrylates such as cyclohexyl (meth)acrylate, bornyl (meth)acrylate, isobornyl (meth)acrylate, dicyclopentenyl (meth)acrylate and dicyclopentenyloxyethyl (meth)acrylate; aromatic (meth)acrylates such as benzyl (meth)acrylate, phenyl (meth)acrylate, phenylcarbitol (meth)acrylate, nonylphenyl (meth)acrylate, nonylphenylcarbitol (meth)acrylate and nonylphenoxy (meth)acrylate; amino group-containing (meth)acrylates such as 2-dimethylaminoethyl (meth)acrylate, 2-diethylaminoethyl (meth)acrylate and 2-tert-butylaminoethyl (meth)acrylate;

phosphorus atom-containing methacrylates such as methacryloxyethyl phosphate, bis-methacryloxyethyl phosphate, methacryloxy ethylphenyl acid phosphate (phenyl P); diacrylates such as ethyleneglycol di(meth)acrylate, diethyleneglycol di(meth)acrylate, triethyleneglycol di(meth)acrylate, tetraethylene di(meth)acrylate, polyethyleneglycol di(meth)acrylate, propyleneglycol di(meth)acrylate, dipropyleneglycol di(meth)acrylate, tripropyleneglycol di(meth)acrylate, 1,4-butanediol di(meth)acrylate, 1,3-butanediol di(meth)acrylate, neopentylglycol di(meth)acrylate, 1,6-hexanediol di(meth)acrylate and bis-glycidyl (meth)acrylate;

polyacrylates such as trimethylolpropane tri(meth)acrylate, pentaerythritol tri(meth)acrylate and dipentaerythritol hexa(meth)acrylate; modified polyol polyacrylates such as bisphenol S ethylene oxide 4-molar modified diacrylate, bisphenol A ethylene oxide 4-molar modified diacrylate, fatty acid-modified pentaerythritol diacrylate, trimethylolpropane propylene oxide 3-molar modified triacrylate and trimethylolpropane propylene oxide 6-molar modified triacrylate, and isocyanuric acid skeleton-containing polyacrylates such as bis(acryloyloxyethyl)monohydroxyethyl isocyanurate, tris(acryloyloxyethyl) isocyanurate and ε-caprolactone-modified tris(acryloyloxyethyl) isocyanurate.

polyester acrylates such as α,ω-diacryloyl-(bisethyleneglycol)-phthalate and α,ω-tetraacryloyl-(bistrimethylolpropane)-tetrahydrophthalate; allyl (meth)acrylate; polycaprolactone (meth)acrylate; (meth)acryloyloxyethyl phthalate; (meth)acryloyloxyethyl succinate; and phenoxyethyl acrylate. There may also be used N-vinyl compounds such as N-vinylpyrrolidone, N-vinylformamide and N-vinylacetamide, epoxy acrylates, urethane acrylates and the like. Urethane acrylates are preferred among these because of their low tack. Compounds having two ethylenic unsaturated bonds in the molecule are particularly preferred for photosensitivity and cured product flexibility. The content of a compound (B) having two or more ethylenic unsaturated bonds in the molecule is preferably about 3-20 wt % of the flame retardant composition for a solder resist.

As examples of the photopolymerization initiator (C) to be used for the invention there may be mentioned benzoin, benzoin alkylethers such as benzoin methylether and benzoin isopropylether, acetophenones such as acetophenone, 2,2-dimethoxy-2-phenylacetophenone, 2,2-diethoxy-2-phenylacetophenone and 1-hydroxycyclohexylphenylketone, aminoacetophenones such as 2-methyl-1-[4-(methylthio)phenyl]-2-morphorinoaminopropanone-1,2-benzyl-2-dimethylamino-1-(4-morphorinophenyl)-butan-1-one and N,N-dimethylaminoacetophenone, anthraquinones such as 2-methylanthraquinone, 2-tert-butylanthraquinone, 2-amylanthraquinone and 2-aminoanthraquinone, thioxanthones such as 2,4-diethylthioxanthone and 2,4-diisopropylthioxanthone, ketals such as acetophenonedimethylketal and benzyldimethylketal, benzophenones such as benzophenone, 4,4′-bisdiethylaminobenzophenone and 4-benzoyl-4′-methyldiphenylsulfide, 2,4,6-trimethylbenzoyl diphenylphosphine oxide, bis(2,4,6-trimethylbenzoyl)-phenylphosphine oxide and bis(2,6-dimethoxybenzoyl)-2,4,4-trimethyl-pentylphosphine oxide. These photopolymerization initiators may be used alone or in combinations of two or more.

If necessary, there may be used a photosensitizing agent or photoinitiator aid, for example, a tertiary amine such as N,N-dimethylaminobenzoic acid ethyl ester, N,N-dimethylaminobenzoic acid isoamyl ester, triethylamine or triethanolamine, either alone or in combinations of two or more. Titanocene compounds such as IRGACURE784 (Ciba Specialty Chemicals) that absorb in the visible light range may be also be used. Photopolymerization initiators and photosensitizing agents (photoinitiator aids) are not limited to these, and any may be used alone or in combinations.

From the standpoint of flame retardance, the photopolymerization initiator (C) preferably includes a phosphorus-containing compound such as 2,4,6-trimethylbenzoyl diphenylphosphineoxide, bis(2,4,6-trimethylbenzoyl)-phenylphosphineoxide or bis(2,6-dimethoxybenzoyl)-2,4,4-trimethyl-pentylphosphineoxide, which is preferably used in an amount of 20-95 wt % of the photopolymerization initiator.

The content of the photopolymerization initiator (C) is preferably about 1-10 wt % and more preferably about 2-8 wt % of the solid portion of the flame retardant composition for a solder resist. If the photopolymerization initiator content is less than about 1 wt %, the curing may be insufficient even under irradiation with active energy rays, it may be necessary to increase the irradiation time, or it may be difficult to achieve satisfactory cured film properties. On the other hand, addition of the photopolymerization initiator at greater than about 10 wt % will not affect the photosetting properties and is economically undesirable.

The method for obtaining the phosphorus-containing epoxy resin (D) to be used for the invention is not particularly restricted, and for example, it may be obtained by reacting an epoxy resin with two or more epoxy groups in the molecule (d) with a phosphorus-containing compound represented by the following general formula (1) or (2):

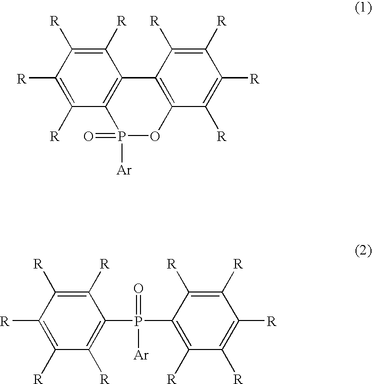

{wherein each R independently represents hydrogen or a C1-6 organic group containing no halogen, and Ar represents the reaction residue of a quinone compound represented by the following general formula (3) or (4):

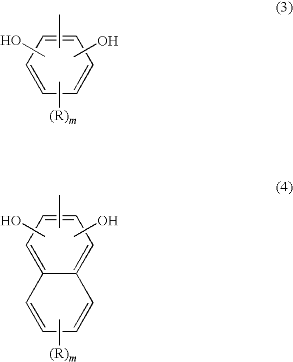

(wherein each R independently represents hydrogen or a C1-6 organic group containing no halogen)}
or represented by the following general formula (5) or (6).

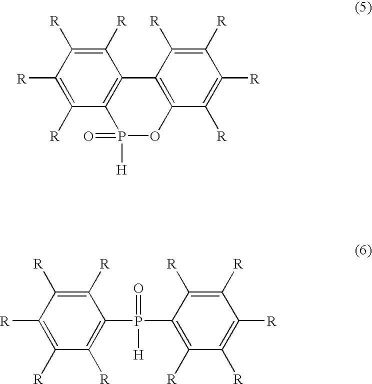

The epoxy resin with two or more epoxy groups in the molecule (d) is not particularly restricted, but is preferably an epoxy resin containing no halogen atoms, since the present invention exhibits an excellent flame retardant effect even without a halogen. An epoxy resin containing no halogen atoms is an epoxy resin containing no halogen atoms in the starting phenol resin that is reacted with epichlorhydrin during production of the epoxy resin, or an epoxy resin that is substantially unmodified with halogen atoms. In other words, it may contain the chlorine included by the normal use of epichlorhydrin, and specifically it preferably has a halogen atom content of no greater than about 5000 ppm. As such epoxy resins there may be used the epoxy resin (a) used for synthesis of the carboxyl group-containing epoxy (meth)acrylate (A1) described above. The epoxy resin used is not limited to a single type, as two or more types may be used in combination, or various modified forms thereof may be used.

As the phosphorus-containing compound (d) there are preferred 10-(2,5-dihydroxyphenyl)-10H-9-oxa-10-phosphaphenanthrene-10-oxide (HCA-HQ, product of Sanko Chemical Industry Co., Ltd.), 9,10-dihydro-9-oxa-10-phosphaphenanthrene-10-oxide (HCA, product of Sanko Chemical Industry Co., Ltd.) and diphenylphosphine oxide.

The reaction between the epoxy resin (d) and the compound of formula (1), formula (2), formula (5) or formula (6) may be conducted by mixing and stirring at a temperature of about 20° C. to 200° C. Here, the phosphorus-containing compound represented by formula (1) or (2) may also be generated by reaction between a phosphorus-containing compound (d) represented by formula (5) or (6) and a quinone represented by formula (3) or (4) in the reaction system. An organic solvent and catalyst may be used in this case.

The reaction may be conducted in the presence of an organic solvent if necessary. The organic solvent used is not particularly restricted but, for example, acetone, methyl ethyl ketone, methyl isobutyl ketone, methanol, ethanol, isopropyl alcohol, n-butanol, methoxypropanol, methylcellosolve, ethylcellosolve, ethylcarbitol, ethyl acetate, xylene, toluene, cyclohexanone and N,N-dimethylformamide are preferred.

The finally obtained phosphorus-containing epoxy resin (D) preferably has an epoxy equivalent value in the range of about 200-1000 gram/equivalent (hereinafter abbreviated as “g/eq”), but from the standpoint of balance between alkali development properties, adhesion with substrates and heat resistance when the composition is used as a solder resist or photosensitive cover lay film, a range of approximately 200-700 q/eq is more preferred.

The phosphorus atom content of the phosphorus-containing epoxy resin (D) is not particularly restricted, and for example, it is preferably about 1-9 wt % from the standpoint of achieving a notable improving effect on the flame retardance, and preferably about 2-6 wt % from the standpoint of moisture resistance and compatibility with other composition components.

Also, the content of the phosphorus-containing epoxy resin (A) in the solid portion of the flame retardant composition for a solder resist is not particularly restricted but is preferably in the range of, for example, 5-40 wt %, from the standpoint of achieving a notable improving effect on the flame retardance.

The hydrated metal compound (E) used for the invention is a metal compound containing water of crystallization, and for example, it may be one having a water of crystallization amount per mole in the range of about 12-60 wt % based on thermal analysis, although this is not a restrictive condition.

From the standpoint of the flame retardant effect, there is preferably used a hydrated metal compound with an isotherm during thermal decomposition of about 400-2500 J/g and more preferably about 600-2500 J/g.

As specific examples of such hydrated metal compounds there may be mentioned aluminum hydroxide, magnesium hydroxide, calcium hydroxide, dawsonite, calcium aluminate, dihydrated gypsum, zinc borate, barium metaborate, zinc hydroxystannate, kaolin, vermiculite and the like. Particularly preferred among these are aluminum hydroxide and magnesium hydroxide.

The particle size of the hydrated metal compound (E) used for the invention is not particularly restricted, but the mean particle size is preferably no greater than about 40 μm, and more preferably no greater than about 2 μm. If the mean particle size is greater than about 40 μm, the transparency of the resist film may be reduced, thus lowering the light transmission, or the outer appearance and smoothness of the coated film surface may be impaired.

The hydrated metal compound (E) used for the invention that has been surface treated with a polar surface treatment agent is especially preferred from the standpoint of improving the moisture resistance and HHBT resistance when the solder resist is cured. As examples of such polar surface treatment agents there may be mentioned silane coupling agents such as epoxysilanes, aminosilanes, vinylsilanes, mercaptosilanes and imidazolesilanes, or titanate coupling agents.

The content of the hydrated metal compound (E) used for the invention is not particularly restricted, but is preferably in the range of about 5-40 wt % as the content in the solid portion of the flame retardant composition for a solder resist. If the content of the hydrated metal compound in the solid portion of the flame retardant composition for a solder resist is less than about 5 wt % the flame retardant effect may be low, and if it is greater than about 40 wt % the flexibility of the cured film will tend to be reduced.

The flame retardant composition for a solder resist according to the invention may be produced by blending the aforementioned components by an ordinary method using a triple roll mill or bead mill. The blending method is not particularly restricted, and for example, a portion of the components may be blended before blending the remaining components, or all of the components may be blended at once. An organic solvent (F) may also be added to the flame retardant composition for a solder resist as necessary for viscosity adjustment. Adjusting the viscosity in this manner will facilitate coating on the target object by roll coating, spin coating, screen coating, curtain coating or the like, as well as printing.

As the organic solvent (F) there may be mentioned ketone-based solvents such as methyl ethyl ketone, methyl isobutyl ketone and cyclohexanone; ester-based solvents such as ethyl acetate, ethyl acetoacetate, γ-butyrolactone and butyl acetate; alcohol-based solvents such as butanol and benzyl alcohol; cellosolve-based and carbitol-based solvents and their ester and ether derivatives; amide-based solvents such as N,N-dimethylformamide, N,N-dimethylacetamide and N-methyl-2-pyrrolidone; dimethylsulfoxide; phenol-based solvents such as phenol and cresol; nitro compound-based solvents; toluene, xylene, hexamethylbenzene and cumene aromatic-based solvents; and aromatic-based or alicyclic-based solvents composed of hydrocarbons such as tetralin, decalin and dipentene. These may be used alone or in combinations of two or more.

The amount of the organic solvent (F) used is preferably adjusted so that the viscosity of the thermosetting composition for a solder resist is about 500-500,000 mPa·s [measured at 25° C. with a Brookfield Viscometer]. The value is more preferably about 800-30,000 mPa·s. This range of viscosity is more suitable and convenient for coating and printing onto target objects. The preferred amount of the organic solvent (F) to be used to produce such a viscosity is about 10-60 wt % in the solid portion of the flame retardant composition for a solder resist. If the amount is greater than about 60 wt % the solid concentration is reduced, and when the photosensitive composition is printed onto a board it may not be possible to obtain a sufficient film thickness with a single printing, thus requiring several printing passes.

The flame retardant composition for a solder resist according to the invention may also employ an epoxy resin (G) other than the phosphorus-containing epoxy resin (D), in a range that does not impair the flame retardance.

As specific examples for the epoxy resin (G) other than the phosphorus-containing epoxy resin (D) there may be mentioned the same ones listed above. These epoxy resins are not limited to only single types for use, as two or more different types may be used in combination, or various modified forms thereof may be used.

The flame retardant composition for a solder resist according to the invention may, if necessary, comprise a phosphoric acid ester compound (H) with a melting point of about 45-150° C. Particularly when the cured flame retardant composition for a solder resist has insufficient flexibility, the use of a phosphoric acid ester compound (H) is preferred in order to increase the flexibility without impairing the flame retardance. As specific examples there may be mentioned PX-200, PX-201 and PX-202 by Daihachi Chemical Industry Co., Ltd. These phosphoric acid ester compounds (H) may be used alone or in mixtures of two or more. The phosphoric acid ester compound (H) is not included in the phosphorus-containing epoxy resin (D).

When a phosphoric acid ester compound (H) is used, the proportion is not particularly restricted but is preferably a content of about 2-10 wt % and more preferably a content of about 2-8 wt % in the solid portion of the flame retardant composition for a solder resist. If the proportion of the phosphoric acid ester compound (H) is too low the flame retardance and flexibility may be insufficient, while if it is too high, bleed-out of the phosphoric acid ester compound may occur on the surface when the cured composition is stored for long periods.

The flame retardant composition for a solder resist according to the invention may also contain an epoxy thermosetting accelerator (I) for the purpose of accelerating curing of the phosphorus-containing epoxy resin (D) or the epoxy resin (G) other than the phosphorus-containing epoxy resin. For example, there may be used amines, quaternary ammonium salts, acid anhydrides such as cyclic aliphatic acid anhydrides, aliphatic acid anhydrides and aromatic acid anhydrides, and nitrogen-containing heterocyclic compounds such as polyamides, imidazoles, triazine compounds and the like, urea compounds or organic metal compounds.

As amines there may be mentioned aliphatic and aromatic primary, secondary and tertiary amines. As examples of aliphatic amines there may be mentioned polymethylenediamine, polyetherdiamine, diethylenetriamine, triethylenetriamine, tetraethylenepentamine, triethylenetetramine, dimethylaminopropylamine, mencenediamine, aminoethylethanolamine, bis(hexamethylene)triamine, 1,3,6-trisaminomethylhexane, tributylamine, 1,4-diazabicyclo[2,2,2]octane and 1,8-diazabicyclo[5,4,0]undecen-7-ene. As examples of aromatic amines metaphenylenediamine, diaminodiphenylmethane, diaminodiphenylmethane, diaminodiphenylsulfone and benzyldimethyldiamine.

As examples of quaternary ammonium salts there may be mentioned quaternary ammonium salts and quaternary alkylaminopropylamines containing tetrabutylammonium ion, tetrahexylammonium ion, dihexyldimethylammonium ion, dioctyldimethylammonium ion, hexatrimethylammonium ion, octatrimethylammonium ion, dodecyltrimethylammonium ion, hexadecyltrimethylammonium ion, stearyltrimethylammonium ion, docosenyltrimethylammonium ion, cetyltrimethylammonium ion, cetyltriethylammonium ion, hexadecylammonium ion, tetradecyldimethylbenzylammonium ion, stearyldimethylbenzylammonium ion, dioleyldimethylammonium ion, N-methyldiethanollaurylammonium ion, dipropanolmonomethyllaurylammonium ion, dimethylmonoethanollaurylammonium ion and polyoxyethylenedodecylmonomethylammonium ion.

As acid anhydrides there may be mentioned aromatic acid anhydrides such as phthalic anhydride, trimellitic anhydride, benzophenonetetracarboxylic anhydride, ethyleneglycol bis(anhydrotrimellitate) and glycerol tris(anhydrotrimellitate), and maleic anhydride, succinic anhydride, methylnadic anhydride, hexahydrophthalic anhydride, tetrahydrophthalic anhydride, polyadipic anhydride, chlorendic anhydride, tetrabromophthalic anhydride, and the like. As polyamides there may be mentioned polyaminoamides with primary or secondary amino groups obtained by condensation reaction of polyamines such as diethylenetriamine or triethylenetetraamine with dimer acids.

As imidazoles there may be mentioned, specifically, imidazole, 2-ethyl-4-methylimidazole, N-benzyl-2-methylimidazole, 1-cyanoethyl-2-undecylimidazolium trimellitate and 2-methylimidazolium isocyanurate.

Triazine compounds are compounds having a 6-membered ring with three nitrogen atoms, and for example, there may be mentioned melamine compounds, cyanuric acid compounds and cyanuric acid-melamine compounds. Specifically, as melamine compounds there may be mentioned melamine, N-ethylenemelamine and N,N′,N″-triphenylmelamine. As cyanuric acid compounds there may be mentioned cyanuric acid, isocyanuric acid, trimethyl cyanurate, tris-methyl isocyanurate, triethyl cyanurate, tris-ethyl isocyanurate, tri(n-propyl) cyanurate, tris(n-propyl) isocyanurate, diethyl cyanurate, N,N′-diethylisocyanurate, methyl cyanurate and methyl isocyanurate. As cyanuric acid-melamine compounds there may be mentioned equimolar mixtures of melamine compounds and cyanuric acid compounds. As urea compounds there may be mentioned toluene bis(dimethylurea), 4,4′-methylene bis(phenyldimethylurea) and phenyldimethylurea.

As organic metal compounds there may be mentioned organic acid metal salts, 1,3-diketone metal chelates and metal alkoxides. Specifically, there may be mentioned organic acid metal salts such as dibutyltin dilaurate, dibutyltin maleate and zinc 2-ethylhexanoate, 1,3-diketone metal chelates such as nickel acetylacetonate and zinc acetylacetonate, and metal alkoxides such as titanium tetrabutoxide, zirconium tetrabutoxide and aluminum butoxide.

The epoxy thermosetting accelerator (I) is preferably a compound with a triazine skeleton. The amount of addition is a catalytic amount, and specifically it is preferred to be about 0.1-3 wt % of the flame retardant composition for a solder resist.

If necessary, a halogen-free coloring agent (J) may also be used in the flame retardant composition for a solder resist according to the invention.

The mixing proportions in the flame retardant composition for a solder resist according to the invention are preferably in the ranges of 30-70 wt % of the alkali-soluble resin (A), 3-20 wt % of the compound having an ethylenic unsaturated group in the molecule (B), 1-10 wt % of the photopolymerization initiator (C), 5-25 wt % of the phosphorus-containing epoxy resin (D), 5-30 wt % of the hydrated metal compound (E), 10-60 wt % of the organic solvent (F), 0-10 wt % of the epoxy resin (G) other than the phosphorus-containing epoxy resin (D), 2-10 wt % of the phosphoric acid ester compound (H), 0.1-3 wt % of the epoxy thermosetting accelerator (I) and 0.05-2 wt % of the coloring agent (J).

The thermosetting composition for a solder resist according to the invention may also contain flow property adjustors for adjustment of the flow property. A flow property adjustor is preferred to allow appropriate adjustment of the flow property of the photosensitive composition when it is coated onto a target object by roll coating, spin coating, screen coating, curtain coating or the like. As examples of flow property adjustors there may be mentioned inorganic and organic fillers, waxes or surfactants. As specific examples of inorganic fillers there may be mentioned talc, barium sulfate, barium titanate, silica, alumina, clay, magnesium carbonate, calcium carbonate and silicate compounds. As specific examples of organic fillers there may be mentioned silicone resins, silicone rubber and fluorine resins. As specific examples of waxes there may be mentioned polyamide waxes and polyethylene oxide waxes. As specific examples of surfactants there may be mentioned silicone oils, higher fatty acid esters and amides. These flow property adjustors may be used alone or in combinations of two or more. Using an inorganic filler is advantageous not only for the flow properties of the photosensitive composition, but also for enhanced cohesion and hardness.

If necessary, additives such as pigments, thermopolymerization inhibitors, thickeners, defoamers, leveling agents and tackifiers can be added to the flame retardant composition for a solder resist according to the invention. As thermopolymerization inhibitors there may be mentioned hydroquinone, hydroquinone monomethyl ether, tert-butyl catechol, pyrogallol, phenothiazine, triethyleneglycol-bis[3-(3-t-butyl-5-methyl-4-hydroxyphenyl)propionate], pentaerythrityl-tetrakis[3-(3,5-di-t-butyl-4-hydroxyphenyl)propionate] and the like. As thickeners there may be mentioned laminar silicates such as hectorite, montmorillonite, saponite, beidellite, stevensite, tetrasilicon mica and taeniolite, as well as intercalated compounds obtained by organic cation treatment of these interlaminar compounds, silica and organic silica, polyvinyl alcohol and cellulose derivatives. Defoaming agents are used to eliminate foam produced during printing, application and curing, and specifically there may be mentioned acrylic-based and silicone-based surfactants. Leveling agents are used to eliminate unevenness of the film surface formed during printing and application, and specifically there may be mentioned acrylic-based and silicone-based surfactants. As tackifiers there may be mentioned imidazole-based, thiazole-based, triazole-based and silane coupling agents. Other additives include, for example, ultraviolet blockers for storage stability, or plasticizers, which may be added in amounts that do not impair the function and effect of the invention.

The flame retardant composition for a solder resist of the invention is applied onto a board or the like to an appropriate thickness, heat treated and dried, and then subjected to exposure, development and thermosetting for curing to obtain a cured composition. The flame retardant composition for a solder resist according to the invention may be employed for a variety of purposes, and since it can form a cured film with heat resistance, hardness, dimensional stability and flexibility, which is resistant to deformation, it is suitable for use as an insulating protective coating for a printed circuit board, and particularly as an insulating protective coating for an FPC board. When forming an insulating protective coating, there may be employed a method in which the photosensitive composition is applied onto a circuit-formed board to a thickness of about 10-100 μm, then dried by heat treatment in a temperature range of about 50-120° C. for about 1-30 minutes, exposed through a negative mask with the desired exposure pattern, developed by removal of the unexposed sections with an alkali developing solution, and thermoset in a temperature range of about 100-180° C. for about 20-60 minutes for curing. The flame retardant composition for a solder resist may also be used as an insulating resin layer between layers of a multilayer multilayer printed circuit board, for example.

The activating light used for exposure may be activating light emitted from a known activating light source such as, for example, a carbon arc, mercury vapor arc, xenon arc lamp or any of various laser devices. The sensitivity of the photopolymerization initiator (C) in the photosensitive layer will usually be greatest in the ultraviolet range, and therefore the activating light source is preferably one which effectively emits ultraviolet rays. Of course, when the photopolymerization initiator (C) is one which is sensitive to visible light, such as 9,10-phenanthrenequinone, for example, visible light may be used as the activating light, emitted from a light source such as a photographic flood lamp or solar lamp instead of the activating light sources mentioned above. The developing solution may be an aqueous alkali solution of potassium hydroxide, sodium hydroxide, sodium carbonate, potassium carbonate, sodium phosphate, sodium silicate, ammonia, an amine, or the like.

The flame retardant composition for a solder resist of the invention may be used as the photosensitive layer of a photosensitive cover lay film. A photosensitive cover lay film possesses a photosensitive layer composed of a photosensitive composition on a support made of a polymer film or the like. The thickness of the dried photosensitive layer is preferably about 5-70 μm. Examples of polymer films that may be used as supports include films made of polyester resins such as polyethylene terephthalate and aliphatic polyesters, or polyolefin resins such as polypropylene and low-density polyethylene, among which films made of polyethylene terephthalate, low-density polyethylene and polypropylene are preferred. The polymer film must layer be removed from the photosensitive layer, and must therefore be one which is easily removable from the photosensitive layer. The thickness of the polymer film is usually about 5-100 μm and is preferably about 10-30 μm.

The photosensitive cover layer film may be produced by a photosensitive layer formation step wherein the photosensitive composition is applied onto the support and dried. By forming a cover film on the formed photosensitive layer, it is possible to produce a photosensitive cover lay film comprising a support, a photosensitive layer and a cover film laminated in that order, with films on both sides of the photosensitive layer. The cover film is released from the photosensitive cover lay film at the time of use, and the presence of the cover films on the photosensitive layer up until the time of use protects the photosensitive layer in order to provide a photosensitive cover lay film with excellent handleability. As cover films there may be used the same materials as for the polymer film used for the support as described above, and the cover film and support may be made of the same material or of different materials, either with the same thickness of different thicknesses.

In order to employ the photosensitive cover lay film for formation of an insulating protective coating for a printed circuit board, first an attachment step is carried out, wherein the photosensitive layer of the photosensitive cover lay film is attached to the board. When a photosensitive cover lay film provided with a cover film is used, the cover film is released to expose the photosensitive layer before contact with the board. The photosensitive layer and board are then thermo-compression bonded with a pressure laminator or vacuum pressure laminator at about 40-120° C. for lamination of the photosensitive layer on the board. This is followed by an exposure step wherein the photosensitive layer is exposed to light through a negative mask with the desired exposure pattern. The support film is then released from the photosensitive layer. This is then followed by a developing step wherein the unexposed sections are removed by development with a developing solution and a thermosetting step wherein the photosensitive layer is thermoset, to allow manufacture of a printed circuit board provided with an insulating protective film on the surface of the board. Such a photosensitive cover lay film may be used to form insulating resin layers between layers of a multilayer printed circuit board. The activating light used for exposure and the developing solution may be the same as described above.

The flame retardant composition for a solder resist of the invention simultaneously satisfies required performance relating to formation of the photosensitive coating, such as photosensitivity, developing properties and shelf life, as well as performance required for an insulating protective coating such as flame retardance, insulating properties, heat resistance, hardness and dimensional stability, and can also form flexible cured films. In particular, such a photosensitive composition which is halogen-free and has flame retardance and flexibility, obtained by using the phosphorus-containing epoxy resin (D), hydrated metal compound (E) and optionally a phosphoric acid ester (H) with a melting point of about 75-150° C. and a phosphorus-containing photopolymerization initiator in combination, is optimally suited for use as an insulating protective coating for thin circuit boards, such as flexible printed circuit boards.

### EXAMPLES

The present invention will now be explained in greater detail by examples and comparative examples. Throughout the examples, the “parts” and “%” values are based on weight, unless otherwise specified. The phosphorus content of the phosphorus-containing epoxy compound (D) was measured by the following method.

### Phosphorus Content Measuring Method

After adding 25 ml of nitric acid and 10 ml of perchloric acid to 1 g of sample and heating to dissolution to a content of 5-10 ml, the solution is diluted with distilled water in a 1000 ml graduated flask. A 10 ml portion of the sample solution is placed in a 100 ml graduated flask, and then after adding 10 ml of nitric acid, 10 ml of a 0.25% aqueous ammonium vanadate solution and 10 ml of a 5% aqueous ammonium molybdate solution, distilled water is added for dilution to the gauge mark and the mixture is shaken and allowed to stand, after which the developed solution is placed in a quartz cell, and the absorbance of the sample and the phosphorus standard solution at a wavelength of 400 nm is measured using a spectrophotometer, referenced against a blank solution. The phosphorus standard solution is 10 ml of a solution of potassium phosphate prepared to P=0.1 mg/ml with distilled water, placed in a 100 ml graduated flask and diluted with distilled water.

The phosphorus content is then determined by the following formula.

Phosphorus content (%)=Absorbance of sample/absorbance of phosphorus standard solution/sample (g)

### Synthesis Example 1

### PUA-1

After measuring out 85.0 g (=0.1 mol) of polytetramethylene glycol (PTG-850SN, product of Hodogaya Chemical Co., Ltd., molecular weight: 850), 93.8 g (=0.7 mol) of dimethylolpropionic acid as a carboxyl group-containing dihydroxy compound and 199.8 g (=0.9 mol) of isophorone diisocyanate as diisocyanate, the components were heated at 50° C. There was charged into the mixture 150 mg of di-n-butyltin dilaurate prior to heating at 80° C. After then introducing into the reactor 90 mg each of p-methoxyphenol and di-t-butylhydroxytoluene, 24.4 g (=0.21 mol) of 2-hydroxyethyl acrylate was added as a hydroxyl group-containing (meth)acrylate. Stirring was continued at 80° C., and reaction was completed upon confirming disappearance of the isocyanate group absorption peak (2280 cm⁻¹) in the infrared absorption spectrum, to obtain a carboxyl group-containing urethane acrylate. Diethyleneglycol monoethylether acetate was used as the solvent for synthesis. In this manner there was obtained a viscous liquid urethane acrylate (PUA-1) with a solid portion acid value of 90 mgKOH/g and a solid concentration of 50 wt %. The weight-average molecular weight was 17,200 and the viscosity (25° C.) was 11,000 mPa·s. The glass transition temperature was 52° C.

### Synthesis Example 2

### D-1

There were reacted 100 parts of a bisphenol F-type epoxy resin with an epoxy equivalent of 172 g/eq (EPICLON830S: product of Dainippon Ink & Chemicals, Inc.), 37 parts of 10-(2,5-dihydroxyphenyl)-10H-9-oxa-10-phosphaphenanthrene-10-oxide (HCA-HQ, product of Sanko Chemical Industry Co., Ltd.) and 0.5 part of triphenylphosphine as a catalyst at 140° C. for 5 hours, to obtain a phosphorus-containing epoxy resin with a phosphorus content (solid portion) of 2.6 wt % and an epoxy equivalent (solid portion) of 434 g/eq. Diethyleneglycol monoethylether acetate was added and the mixture was heated to 80° C. to obtain a solution with a solid content of 75 wt %. This solution was named resin (D-1).

### Synthesis Example 3

### D-2

There were reacted 100 parts of a bisphenol A-type epoxy resin with an epoxy equivalent of 186 g/eq (EPIKOTE828: product of Japan Epoxy Resin Co., Ltd.), 30 parts of 10-(2,5-dihydroxyphenyl)-10H-9-oxa-10-phosphaphenanthrene-10-oxide (HCA-HQ, product of Sanko Chemical Industry Co., Ltd.) and 0.5 part of triphenylphosphine as a catalyst at 140° C. for 5 hours, to obtain a phosphorus-containing epoxy resin with a phosphorus content (solid portion) of 2.2 wt % and an epoxy equivalent (solid portion) of 411 g/eq. Diethyleneglycol monoethylether acetate was added and the mixture was heated to 80° C. to obtain a solution with a solid content of 75 wt %. This solution was named resin (D-2).

### Synthesis Example 4

### D-3

There were reacted 100 parts of a cresol-novolac type epoxy resin with an epoxy equivalent of 219 g/eq (KAYARAD EOCN-104S: product of Nippon Kayaku Co., Ltd.), 40 parts of 9,10-dihydro-9-oxa-10-phosphaphenanthrene-10-oxide (HCA, product of Sanko Chemical Industry Co., Ltd.), 0.5 part of triphenylphosphine as a catalyst and 47 parts of diethyleneglycol monoethylether acetate as a solvent at 140° C. for 5 hours, to obtain a phosphorus-containing epoxy resin with a phosphorus content (solid portion) of 4.1 wt % and an epoxy equivalent (solid portion) of 369 g/eq. This solution was named resin (D-3).

### Examples 1-5, Comparative Examples 1-4

### Preparation of Flame Retardant Composition for Solder Resist

After combining the components in the proportions (wt %) listed in Table 1 below, the mixture was passed three times through a triple roll mill to prepare a base resin and curing agent. During preparation with the triple roll mill, there was added diethyleneglycol monoethylether acetate/petroleum naphtha=60/40 wt % as a solvent for adjustment of the base resin solid concentration to 71 wt % and the curing agent solid concentration to 80 wt %.

Each of the obtained flame retardant compositions was subjected to the following evaluation.

TABLE 1

| | | | | | | | | | Comp. | Comp. | Comp. |
|---|---|---|---|---|---|---|---|---|---|---|---|
| Contents (solid portion) (parts by wt.) | | | Example 1 | Example 2 | Example 3 | Example 4 | Example 5 | Comp. Ex. 1 | Ex. 2 | Ex. 3 | Ex. 4 |
| Base | (A) | PUA-1 (synthesis example 1) | 100 | 100 | 100 | 100 | 100 | 100 | 100 | — | 100 |
| resins | | CYCLOMER P ACA200 *1 | — | — | — | — | — | — | — | 100 | — |
| | (B) | Ebecryl 6700 *2 | 20 | 20 | 20 | 20 | 20 | 20 | 20 | 20 | 20 |
| | | Pentaerythritol | 7 | 7 | 7 | 7 | 7 | 7 | 7 | 7 | 7 |
| | | triacrylate | | | | | | | | | |
| | (C) | KAYACURE DETX-S *3 | 0.4 | 0.4 | 0.4 | 0.4 | 0.4 | 0.4 | 0.4 | 0.4 | 0.4 |
| | | IRGACURE 907 *4 | 3.5 | 3.5 | 3.5 | 3.5 | 3.5 | 3.5 | 3.5 | 3.5 | 3.5 |
| | | Lucirin TPO *5 | 8 | 8 | 8 | 8 | 8 | 8 | 8 | 8 | 8 |
| | (E) | HIGILITE H-43STE *6 | 36 | 36 | 36 | 36 | 36 | 0 | 36 | 36 | 36 |
| | (H) | PX-200 *7 | 13 | 13 | 13 | 13 | 7 | 13 | 13 | 13 | — |
| | CR-741 *8 | | — | — | — | — | — | — | — | — | 13 |
| | (J) | Phthalocyanine blue | 0.7 | 0.7 | 0.7 | 0.7 | 0.7 | 0.7 | 0.7 | 0.7 | 0.7 |
| | AEROSIL #380 *9 | | 4 | 4 | 4 | 4 | 4 | 4 | 4 | 4 | 4 |
| | BYK-070 *10 | | 2.6 | 2.6 | 2.6 | 2.6 | 2.6 | 2.6 | 2.6 | 2.6 | 2.6 |
| Curing | (D) | D-1 (synthesis example 2) | 53 | — | — | 28 | 53 | 53 | — | 53 | 53 |
| agents | | D-2 (synthesis example 3) | — | 53 | — | — | — | — | — | — | — |
| | | D-3 (synthesis example 4) | — | — | 53 | — | — | — | — | — | — |
| | (G) | EPIKOTE 828 *11 | — | — | — | 25 | — | — | 53 | — | — |
| | (I) | Curezol VT *12 | 1.1 | 1.1 | 1.1 | 1.1 | 1.1 | 1.1 | 1.1 | 1.1 | 1.1 |

| | | | | | | | | | |
|---|---|---|---|---|---|---|---|---|---|
| SG-2000 *13 | 10 | 10 | 10 | 10 | 10 | 10 | 10 | 10 | 10 |
| AEROSIL #380 *9 | 1 | 1 | 1 | 1 | 1 | 1 | 1 | 1 | 1 |

| | | | | | | | | | |
|---|---|---|---|---|---|---|---|---|---|
| Total | 260.3 | 260.3 | 260.3 | 260.3 | 254.3 | 224.3 | 260.3 | 260.3 | 260.3 |

*1 CYCLOMER P ACA200: Acryl copolymer resin (Daicel Chemical Industries, Ltd., solid concentration = 47 wt %, solid acid value = 107 mgKOH/g, glass transition temperature = 137° C.)
*2 Ebecryl 6700: Bifunctional urethane acrylate (Daicel Chemical Industries, Ltd.)
*3 KAYACURE DETX-S: 2,4-Diethylthioxanthone (Nippon Kayaku Co., Ltd.)
*4 IRGACURE 904: 2-Methyl-[4-(methylthio)phenyl]-2-morphorino-1-propanone (Chiba Specialty Chemicals.)
*5 Lucirin TPO: 2,4,6-Trimethylbenzoyldiphenylphosphine oxide
*6 HIGILITE H-43STE: Silane coupling agent-modified aluminum hydroxide (Showa Denko K.K.)
*7 Px-200: Aromatic condensed phosphoric acid ester (Daihachi Chemical Industry Co., Ltd., melting point = 95° C.)
*8 CR-741: Aromatic condensed phosphoric acid ester (Daihachi Chemical Industry Co., Ltd., melting point = 5° C.)
*9 AEROSIL #380: Silicon dioxide (Nippon Aerosil Co., Ltd.)
*10 BYK-070: Defoaming agent (Bigchemi Japan Co., Ltd.)
*11 EPIKOTE 828: Bisphenol A-type epoxy resin (Japan Epoxy Resins Co., Ltd., epoxy equivalent = 186 g/eq)
*12 Curezol VT: 2,4-Diamino-6-vinyl-s-triazine (Shikoku Chemicals Corp.)
*13 SG-2000: Talc (Nippon Talc Co., Ltd.)

### Fabrication of Laminated Test Piece

An ink obtained by mixing the base resin and curing agent was coated onto a board by screen printing with a 100 mesh polyester plate. This was set in a hot air circulating drier at 70° C. and dried for 30 minutes. The board used for evaluation was the following (1) or (2).

(1) Print board (UPISEL™ N, Ube Kosan Co., Ltd.) composed of a polyimide film (25 μm thickness) with a copper foil (16 μm thickness) laminated on one side, which had been cleaned with 10% aqueous ammonium sulfate, rinsed with water and dried with an air stream.

(2) 25 μm-thick polyimide film (CAPTONE™ 100H, Toray-DuPont Co., Ltd.)

### Laminated Test Piece Exposure, Development and Thermosetting

Each of the obtained laminated test pieces was exposed at 500 mJ/cm² (measured at a wavelength of 365 nm) using an HMW-680GW exposure apparatus with a metal halide lamp (product of Oak Technologies). Next, the unexposed sections were removed by spraying for 60 seconds with a 1 wt % aqueous sodium carbonate solution at a temperature of 30° C. and a spray pressure of 0.2 MPa, and then for 60 seconds with water at a temperature of 30° C. and a spray pressure of 0.15 MPa, and heat treatment was conducted at 150° C. for 60 minutes to obtain an FPC laminated board (used as evaluation board (1)) and a polyimide laminated board (used as evaluation board (2)).

A Hitachi 21-step tablet was used as the negative pattern for exposure during fabrication of the photosensitivity evaluation sample. During fabrication of the soldering heat resistance evaluation sample, the negative pattern used left a copper foil in a 1 cm×1 cm square and 2 cm-long 1 mm/1 mm (line/space) pattern within a 4 cm×6 cm area. No negative pattern was used during fabrication of the other evaluation samples.

### Physical Property Evaluation

The physical properties were evaluated in the following manner. The results are shown below in Table 2. The “flammability” and “flexibility” for each evaluation were determined using a polyimide laminated board, and the other evaluations were carried out using an FPC board.

TABLE 2

| | | | | | | Comp. | Comp. | Comp. | Comp. |
|---|---|---|---|---|---|---|---|---|---|
| | Example 1 | Example 2 | Example 3 | Example 4 | Example 5 | Ex. 1 | Ex. 2 | Ex. 3 | Ex. 4 |
| Cured filament thickness (μm) | 24 | 24 | 24 | 24 | 24 | 24 | 24 | 24 | 24 |
| Flammability | VTM-0 | VTM-0 | VTM-0 | VTM-0 | VTM-0 | NOT | NOT | VTM-0 | VTM-0 |
| Tack | A | A | A | A | A | A | C | C | C |
| Developing property | A | A | A | A | A | A | A | A | A |
| Photosensitivity (step) | 8 | 8 | 8 | 8 | 8 | 7 | 8 | 8 | 8 |
| Flexibility | A | A | A | A | A | A | C | C | A |
| Bleed | A | A | A | A | A | A | A | A | C |
| Soldering heat resistance | 3 | 3 | 3 | 3 | 3 | 3 | 3 | 4 | 2 |
| (times) | | | | | | | | | |
| PCT resistance | A | A | A | A | A | A | A | C | C |

### Evaluation

### Flammability

A flammable test piece was prepared in the following manner. An ink obtained by mixing the base resin and curing agent was formed on one side of a 25 μm-thick, 200 mm×50 mm polyimide film (CAPTONE™ 100H, Toray-DuPont Co., Ltd.) by screen printing with a 100 mesh polyester plate. This was set in a hot air circulating drier at 70° C. and dried for 30 minutes. The ink was then printed in the same manner on the opposite side of the test piece, which was again set in the hot air circulating drier at 70° C. and dried for 30 minutes. After UV irradiation at 500 mJ/cm², it was subjected to alkali development and thermosetting at 150° C. for 60 minutes. The sample was conditioned at a temperature of 23° C. and a relative humidity of 50% for 48 hours and used as a sample for flammability testing. The flammable characteristics were evaluated according to the Tests for Flammability of Plastic Materials (94UL-VTM) of the Underwriters Laboratories Inc. U.S.A. (UL).

The “VTM” and “NOT” abbreviations in Table 2 signify the following.

VTM-0: Rating that satisfies all of the following requirements.

(1) Flaming combustion time of no greater than 10 seconds for any test piece after termination of each burner flame.

(2) Total flaming combustion time of no greater than 50 seconds after applying a total of 10 burner flames to 5 test pieces of any set.

(3) Flaming or glowing combustion failed to reach 125 mm mark line.

(4) Flaming drops failed to ignite absorbent cotton.

(5) Total flaming and glowing combustion time for each test piece of no greater than 30 seconds after termination of second burner flame.

(6) Where only one of five test pieces in a set failed to satisfy the requirements or the total flaming combustion time ranges from 51 to 55 seconds, upon retesting all of the five test pieces satisfied requirements (1) to (5).

VTM-1: Rating that satisfies all of the following requirements.

(1) Flaming combustion time of no greater than 30 seconds for any test piece after termination of each burner flame.

(2) Total flaming combustion time of no greater than 250 seconds after applying a total of 10 burner flames to 5 test pieces of any set.

(3) Flaming or glowing combustion failed to reach 125 mm mark line.

(4) Flaming drops failed to ignite absorbent cotton.

(5) Total flaming and glowing combustion time for each test piece of no greater than 60 seconds after termination of second burner flame.

(6) Where only one of five test pieces in a set failed to satisfy the requirements or the total flaming combustion time ranges from 251 to 255 seconds, upon retesting all of the five test pieces satisfied requirements (1) to (5).

VTM-2: Rating that satisfies all of the following requirements.

(1) Flaming combustion time of no greater than 30 seconds for any test piece after termination of each burner flame.

(2) Total flaming combustion time of no greater than 250 seconds after applying a total of 10 burner flames to 5 test pieces of any set.

(3) Flaming or glowing combustion failed to reach 125 mm mark line.

(4) Flaming drops may ignite absorbent cotton.

(5) Total flaming and glowing combustion time for each test piece of no greater than 60 seconds after termination of second burner flame.

(6) Where only one of five test pieces in a set failed to satisfy the requirements or the total flaming combustion time ranges from 251 to 255 seconds, upon retesting all of the five test pieces satisfied requirements (1) to (5).

NOT: Cases which fall within none of the above ratings.

### Tack

After printing a flame retardant composition for a solder resist onto an FPC board and drying at 70° C. for 30 minutes, it was allowed to cool for 30 minutes and the obtained test piece was used for evaluation of the photosensitive layer surface tack by finger contact at room temperature, according to the following scale.

A: Absolutely no stickiness

B: Only slight stickiness

C: Stickiness

### Developing Property

The flame retardant composition for a solder resist was printed and dried to obtain an FPC laminate board, which was developed for 1 minute under conditions with a temperature of 30° C. and a spray pressure of 0.2 MPa using 1 wt % aqueous sodium carbonate as the developing solution, and after cleaning for 1 minute under conditions with a spray pressure of 0.2 MPa, the development residue was visually observed. The symbols shown in Table 2 above indicate the following.

A: Successful development

C: Development residue observed

### Photosensitivity

A Hitachi 21-step tablet was stacked onto the sample as a negative pattern, and after exposure (500 mJ/cm²) and developing treatment, the step number of the step tablet of the photoset film formed on the resulting FPC laminated board was recorded to evaluate the photosensitivity of the curable flame retardant composition. The photosensitivity is expressed as the step number of the step tablet, with a higher step number of the step tablet indicating higher photosensitivity.

### Flexibility

A polyimide laminated board was folded 180° for 1 second at a pressure of 0.5 MPa, with the photosensitive layer-composed cured film side outward. The presence of cracking in the cured film was determined using a 30× optical microscope.

A: No cracking of cured film

C: Cracking of cured film

### Bleed

After storing the polyimide laminated board for 2 months in an incubator at 40° C., evaluation was conducted by finger contact on and visual observation of the test piece surface, according to the following scale. The symbols shown in Table 2 above indicate the following.

A: No sticking or bleeding observed

C: Sticking or bleeding observed

### Soldering Heat Resistance

Following the test method of JIS•C-6481, a rosin-based flux was applied onto the FPC laminated board surface which was then floated for 5 seconds in a solder bath at 260° C., and this cycle was repeated while visually observing the cured film after each cycle to confirm the complete absence of “blistering” and “solder sinking” or other types of changes; the maximum number of cycles without change was recorded.

### PCT Resistance

The FPC laminated board with the resist coating formed therein under the conditions described above was treated with a PCT apparatus (ESPEC HAST CHAMBER EHS-411M by Tabai Corp.) for 96 hours under conditions of 121° C., 0.2 MPa, and the condition of the cured coating was evaluated.

A: No peeling, coloration or elution

B: Peeling, coloration or elution

C: Extensive peeling, coloration and elution

### EFFECT OF THE INVENTION

The flame retardant composition for a solder resist according to the invention exhibits excellent developing properties and light sensitivity for formation of a solder resist pattern by selective exposure to active energy rays through a patterned film and development of the unexposed sections, and because the obtained cured composition is halogen-free, has a high level of flame retardance and satisfies both requirements of flexibility and tack-free properties, it is particularly suitable as an FPC liquid solder resist ink composition or photosensitive cover lay film.

1. A flame retardant composition for a solder resist, comprising
(A) an alkali-soluble resin comprising either or both (A1) a carboxyl group-containing epoxy (meth)acrylate or (A2) a carboxyl group-containing urethane (meth)acrylate obtained by reacting an epoxy resin with two or more epoxy groups in the molecule (a), an unsaturated group-containing monocarboxylic acid (b) and a polybasic acid anhydride (c);
(B) a compound having an ethylenic unsaturated group in the molecule;
(C) a photopolymerization initiator;
(D) a phosphorus-containing epoxy resin obtained by reacting an epoxy resin with two or more epoxy groups in the molecule (d) with a phosphorus-containing compound represented by the following general formula (1) or (2): 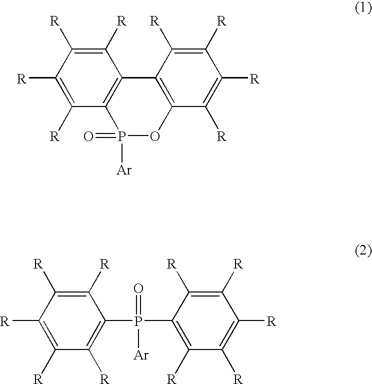
{wherein each R independently represents hydrogen or a C1-6 organic group containing no halogen, and Ar represents the reaction residue of a quinone compound represented by the following general formula (3) or (4): 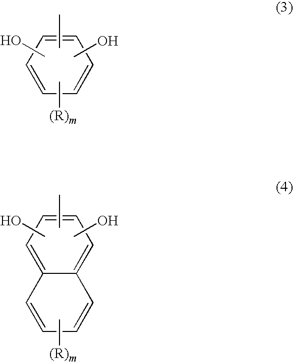
(wherein each R independently represents hydrogen or a C1-6 organic group containing no halogen, and m represents an integer of 0-3)}
or represented by the following general formula (5) or (6): 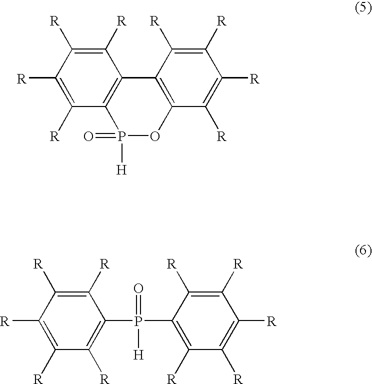
{wherein each R independently represents hydrogen or a C1-6 organic group containing no halogen}; and
(E) a hydrated metal compound.

2. A flame retardant composition for a solder resist according to claim 1, wherein said carboxyl group-containing epoxy (meth)acrylate (A1) is a carboxyl group-containing bisphenol-type epoxy (meth)acrylate (A1-1).

3. A flame retardant composition for a solder resist according to claim 1, wherein said alkali-soluble resin (A) has a solid portion acid value of 30-150 mgKOH/g, a weight-average molecular weight of 4000-40,000 and a glass transition temperature of −60° C. to 60° C.

4. A flame retardant composition for a solder resist according to claim 1, wherein said polybasic acid anhydride (c) is a polybasic acid anhydride selected from the group consisting of phthalic anhydride, tetrahydrophthalic anhydride, hexahydrophthalic anhydride, methylhexahydrophthalic anhydride, endomethylenetetrahydrophthalic anhydride and methylendomethylenetetrahydrophthalic anhydride.

5. A flame retardant composition for a solder resist according to claim 1, wherein 30-100 wt % of said alkali-soluble resin (A) is a carboxyl group-containing urethane (meth)acrylate (A2).

6. A flame retardant composition for a solder resist according to claim 1, wherein said compound having an ethylenic unsaturated group in the molecule (B) is urethane acrylate (B-1).

7. A flame retardant composition for a solder resist according to claim 1, wherein 70-100 wt % of the compound having an ethylenic unsaturated group in the molecule (B) is a compound having two ethylenic unsaturated groups in the molecule.

8. A flame retardant composition for a solder resist according to claim 1, wherein 20-95 wt % of said photopolymerization initiator (C) is a phosphorus-containing photopolymerization initiator.

9. A flame retardant composition for a solder resist according to claim 1, wherein the epoxy equivalent of said phosphorus-containing epoxy resin (D) is 200-700 g/eq.

10. A flame retardant composition for a solder resist according to claim 1, wherein the phosphorus content of said phosphorus-containing epoxy resin (D) is in the range of 1-9 wt %.

11. A flame retardant composition for a solder resist according to claim 1, wherein the content of said phosphorus-containing epoxy resin (D) in the solid portion of the flame retardant composition for a solder resist is in the range of 5-40 wt %.

12. A flame retardant composition for a solder resist according to claim 1, wherein the endotherm during thermal decomposition of said hydrated metal compound (E) is 400-2500 J/g.

13. A flame retardant composition for a solder resist according to claim 1, wherein said hydrated metal compound (E) is aluminum hydroxide and/or magnesium hydroxide.

14. A flame retardant composition for a solder resist according to claim 1, wherein the content of said hydrated metal compound (E) in the solid portion of the flame retardant composition for a solder resist is in the range of 5-40 wt %.

15. A flame retardant composition for a solder resist according to claim 1, wherein said hydrated metal compound (E) is a hydrated metal compound treated with a coupling agent at a proportion of 0.3-3.0 wt %.

16. A flame retardant composition for a solder resist according to claim 1, which further comprises (F) an organic solvent.

17. A flame retardant composition for a solder resist according to claim 1, which further comprises (G) an epoxy resin other than said phosphorus-containing epoxy resin (D).

18. A flame retardant composition for a solder resist according to claim 1, which further comprises (H) a phosphoric acid ester compound with a melting point of 75° C. to 150° C.

19. A flame retardant composition for a solder resist according to claim 1, which further comprises (I) an epoxy thermosetting accelerator.

20. A flame retardant composition for a solder resist according to claim 19, wherein said epoxy thermosetting accelerator (I) has a triazine skeleton.

21. A flame retardant composition for a solder resist according to claim 1, which further comprises (J) a halogen-free coloring agent.

22. A flame retardant composition for a solder resist according to claim 21, wherein the mixing proportions in said flame retardant composition for a solder resist are 30-70 wt % of the alkali-soluble resin (A), 3-20 wt % of the compound having an ethylenic unsaturated group in the molecule (B), 1-10 wt % of the photopolymerization initiator (C), 5-25 wt % of the phosphorus-containing epoxy resin (D), 5-30 wt % of the hydrated metal compound (E), 10-60 wt % of the organic solvent (F), 0-10 wt % of the epoxy resin (G) other than the phosphorus-containing epoxy resin (D), 2-10 wt % of the phosphoric acid ester compound (H), 0.1-3 wt % of the epoxy thermosetting accelerator (I) and 0.05-2 wt % of the coloring agent (J).

23. A flame retardant composition for a solder resist according to claim 1, wherein the phosphorus content of the solid portion of the flame retardant composition for a solder resist is 1.0-5.0 wt %.

24. A flame retardant composition for a solder resist according to claim 1, having a viscosity of 500-500,000 mPa·s (25° C.).

25. A cured composition obtained by curing a flame retardant composition for a solder resist according to claim 1.

26. A method for curing a flame retardant composition, comprising coating a base with a flame retardant composition for a solder resist according to claim 1 and drying for 1-30 minutes in a temperature range of 50-120° C. to a thickness of 5-100 μm, and then subjecting it to exposure, development and thermosetting.

27. A flame retardant cover lay film comprising a photosensitive layer formed from a flame retardant composition for a solder resist according to claim 1, on a support.

28. A flame retardant cover lay film according to claim 27, wherein said support is a polyester film.

29. A method for production of a flame retardant cover lay film, comprising coating a flame retardant composition for a solder resist according to claim 1 onto a support and drying it, to form a photosensitive layer.

30. An insulating protective film comprising a flame retardant composition for a solder resist according to claim 1.

31. A printed circuit board comprising an insulating protective film according to claim 30.

32. A flexible printed circuit board comprising an insulating protective film according to claim 30.

33. A method for production of a printed circuit board, comprising an attachment step in which the photosensitive layer of a flame retardant cover lay film according to claim 27 is attached to a base, an exposure step in which the photosensitive layer is exposed, a development step following the exposure step and a thermosetting step in which the photosensitive layer is thermoset.

34. An electronic part comprising a cured composition according to claim 25.
